(19) United States
(12) Patent Application Publication
(10) Pub. No.: US 2018/0187843 A1
(43) Pub. Date: Jul. 5, 2018

(54) Christmas Decorative Lamp Structure with safety Arrangement

(71) Applicant: HOLIDAY DESIGNS CRAFTS SHENZHEN LTD, Shenzhen (CN)

(72) Inventor: Chun Ting WEI, Shenzhen (CN)

(73) Assignee: HOLIDAY DESIGNS CRAFTS SHENZHEN LTD

(21) Appl. No.: 15/686,038

(22) Filed: Aug. 24, 2017

(30) Foreign Application Priority Data
Jan. 5, 2017 (CN) 201720012764.1

(51) Int. Cl. F21S 4/10; H01L 27/02; F21V 23/00

(52) U.S. Cl. CPC F21S 4/10; F21Y 2115/10; F21V 23/00; H01L 27/0255

(57) ABSTRACT

A decorative lamp structure which includes at least one set of light emitting elements, a power connector and a connecting wire. Each set of light emitting elements includes a plurality of light emitting elements spacedly connected in series on the connecting wire. Each light emitting element is connected to a bidirectional diode in parallel. When one or more of the light emitting element is faulty or damaged, the bidirectional diode of the faulty or damaged light emitting element is triggered and turned on so that the light emitting elements in the same set of light emitting elements are capable of working safely at a constant voltage. The connecting wire has two terminals connecting to the power connector respectively. In other words, when one or more light beads fails, the remaining light beads can still work under normal voltage and hence the Christmas decorative lamp structure can still operate safely.

### CROSS REFERENCE OF RELATED APPLICATION

This is a US national application which claimed priority of Chinese application number 201720012764.1, filing date Jan. 5, 2017. The contents of this specification, including any intervening amendments thereto, are incorporated herein by reference.

### BACKGROUND OF THE PRESENT INVENTION

### Field of Invention

The present invention relates to a decorative lamp structure and, more particularly to a Christmas decorative lamp structure in which the non-faulty lamp beads are capable of working safely at a normal voltage when one or more of the lamp beads fails.

### Description of Related Arts

It is well known that Christmas is an important festival in the world. Christmas decoration lights are a very important element in Christmas festival for celebration. Christmas lighting is not only widely used during the Christmas time, but also for other festive celebration lighting decoration to add festive atmosphere through the colorful lighting in the New Year and the Chinese New Year. The existing Christmas decorative lights use light string structure in which all of its lamp beads are connected in series with each other. This type of Christmas decoration lamp structure has an obvious drawback. Because during the lighting process of the Christmas lights, one or more of its dozens of lamp beads within each group will inevitably go out due to a fault or a defect. When one or more of the lamp beads is faulty, it will lead to an increase in voltage to the other lamp beads and that the other lamp beads may fail or burn after working under high voltage state for a certain period of time. In this case, the maintenance personnel need to replace the faulty lamp beads, thus affecting the normal operation of Christmas lights. For this reason, some people use thermistor and lamp beads connecting in parallel to solve the above problems. However, since this structure of the decorative lights will have a relative great fluctuation in current and voltage of the entire circuit when a particular lamp bead is faulty, thus resulting in flickering of all lamp beads. Also, the instantaneous peak voltage and current surge may damage other components while the heating and the temperature increasing thermistor also has posed a significant security risk.

### SUMMARY OF THE PRESENT INVENTION

An object of the present invention is to solve the above problems and provide a Christmas decorative lighting structure with safety arrangement which can maintain its operation under normal voltage when one or more of its light beads are faulty and burnt.

Additional advantages and features of the invention will become apparent from the description which follows, and may be realized by means of the instrumentalities and combinations particular point out in the appended claims.

According to the present invention, the foregoing and other objects and advantages are attained by a Christmas decorative lamp structure with safety arrangement which comprises: at least one set of light emitting elements, a power connector and a connecting wire, characterized in that: each of the set of light emitting elements comprises: a plurality of light emitting elements connected in series to the connecting wire, wherein each light emitting element connected in parallel to a bidirectional diode, thereby when one or more of the light emitting element is faulty or damaged, the bidirectional diode of the faulty or damaged light emitting element is triggered and turned on so that the light emitting elements of the set of light emitting elements which is not faulty or damaged are capable of working safely at a constant voltage, wherein the connecting wire has two terminals connecting to the power connector respectively.

Preferably, each light emitting element comprises a light bead and a light holder, wherein the light bead has one end terminal connecting to the light holder, wherein the light holder electrically connected to the connecting wire.

Preferably, the light bead comprises a light emitting portion having a columnar structure and a connecting portion coupling to the light emitting portion, wherein the connecting portion is made of insulating materials and has rib-like projections on its inner side and its outer side respectively, wherein the light emitting portion is inserted into the connecting portion, wherein the light emitting portion has two electrode wires extended outside from a tail portion of the connecting portion and folded to an outer side.

Preferably, the light emitting element is LED lamp bead or tungsten lamp bead. Preferably, the light holder comprises a main body, a conductive sheet and a diode support, wherein the main body of the light holder is made of insulating materials and has a sleeve-shaped construction, wherein the main body of the light holder has a step element at an inner and upper side thereof, the main body of the light holder has a cross-shaped groove on an inner wall at a bottom side thereof, wherein the cross-shaped groove has two sets of symmetrical groove portions and one conductive sheet is secured on each of the symmetrical groove portion of one set of symmetrical groove portions, wherein the conductive sheet is electrically connected to the connecting wire, wherein the diode support has a cross-shaped diode connecting portion and an extending portion downwardly extended from the diode connecting portion, wherein the diode connecting portion has a diode positioning hole transversely provided thereon, wherein the diode support is inserted inside the cross-shaped groove of the main body of the light holder.

Preferably, the main body of the light holder has a U-shaped snap seat protruded outwardly at an outer side on an upper portion, wherein the connecting portion of the light bead has a bendable buckle at an outer side for coupling with the snap seat.

Preferably, the bidirectional diode is secured inside the diode positioning hole of the diode support, wherein the bidirectional diode has two terminals extended from two sides of the diode connecting portion and bended to a top portion thereof so as to connect to the two electrode wires of the light bead.

Preferably, the power connector comprises a power plug at one end of the connecting wire and a power socket at the other end of the connecting wire, wherein the power plug is arranged for connecting to an external power source while the power socket is arranged for expansion for connecting to other power plug of another set of light emitting elements.

Preferably, the decorative lamp structure with safety arrangement comprises more than one set of light emitting elements and the sets of light emitting elements are connected in parallel.

The present invention has the advantageous effect that it effectively solves the safely problem of Christmas decorative lights when one or more of the light beads are faulty. The Christmas decorative lamp structure of the present invention, through connecting bidirectional diode in parallel, effectively avoid the increased in voltage to non-faulty lamp beads from bearing the additional voltage of faulty lamp beads when one or more lamp beads are faulty by triggering the connection of the bidirectional diode of each lamp bead, thus the drawback of increased in voltage and replacement of faulty lamp beads, which will affect the operation of the Christmas decorative lights, are prevented. Also, when one or more of the lamp beads are not working properly, the bidirectional diode is triggered and is able to provide a stabilizing effect on the voltage, thus a normal voltage can be maintained even at the instantaneous moment of lamp bead failure. As a result, the normal operation of the Christmas decorative light can be ensured. The present invention also has the advantages of simple structure and easy implementation.

Still further objects and advantages will become apparent from a consideration of the ensuing description and drawings. These and other objectives, features, and advantages of the present invention will become apparent from the following detailed description, the accompanying drawings, and the appended claims.

### BRIEF DESCRIPTION OF THE DRAWINGS

FIG. 1 is a perspective view illustration of a light emitting element according to a preferred embodiment of the present invention.

FIG. 2 is a sectional view illustration of the light emitting element according to the above preferred embodiment of the present invention.

FIG. 3 is a partial exploded view illustration of the light emitting element according to the above preferred embodiment of the present invention.

FIG. 4 is a top perspective view illustration of a light holder according to the above preferred embodiment of the present invention.

FIG. 5 is a perspective view illustration of a light emitting element according to another preferred embodiment of the present invention.

FIG. 6 is a sectional view illustration of the light emitting element according to the above another preferred embodiment of the present invention.

FIG. 7 is a partial exploded view illustration of the light emitting element according to the above another preferred embodiment of the present invention.

FIG. 8 is a schematic circuit diagram showing one set of light emitting elements according to the preferred embodiment of the present invention.

FIG. 9 is a schematic circuit diagram showing two sets of light emitting elements according to the preferred embodiment of the present invention.

FIG. 10 is a schematic circuit diagram showing two sets of light emitting elements according to another preferred embodiment of the present invention.

### DETAILED DESCRIPTION OF THE PREFERRED EMBODIMENT

The Christmas decorative lamp structure with safety arrangement according to the preferred embodiment of the present invention is further described with the accompanying drawings as follows.

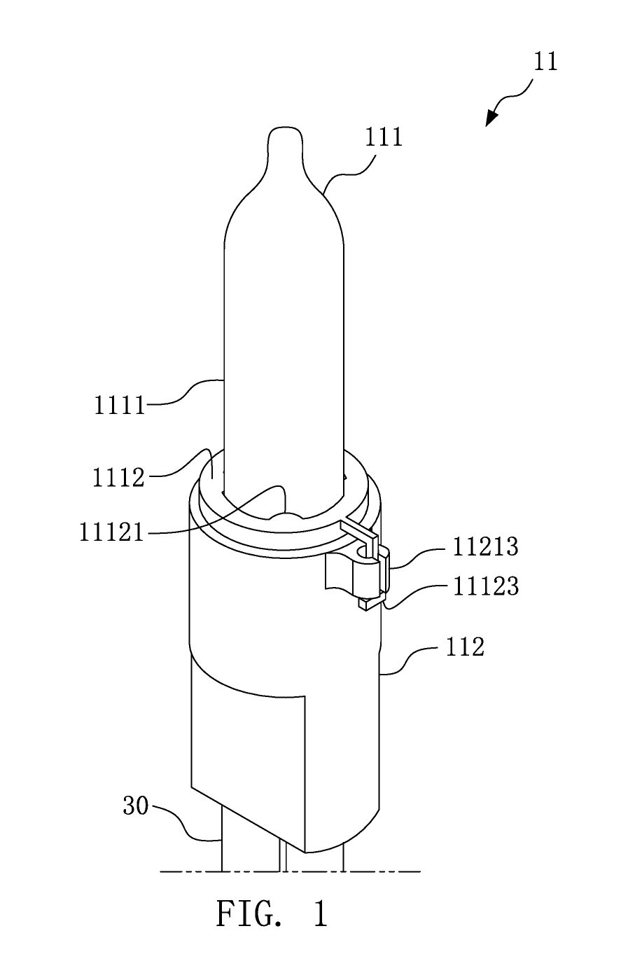

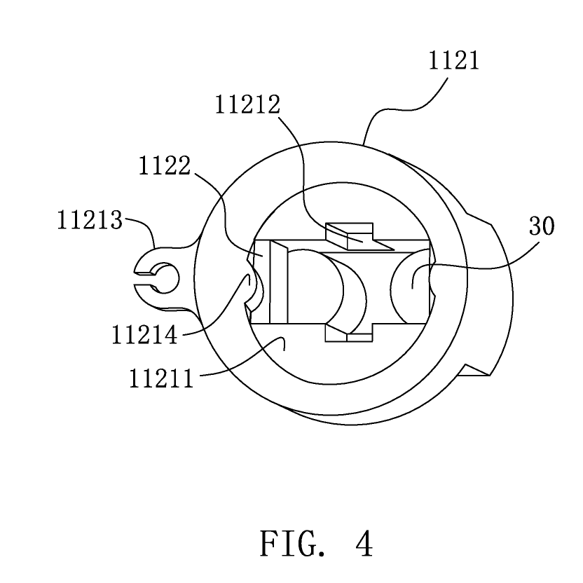

Referring to FIG. 1 to FIG. 7 of the drawings, the Christmas decorative lamp structure with safety arrangement according to the preferred embodiment of the present invention comprises a set of light emitting elements 10, a power connector 20, a connecting wire 30 and a bidirectional diode 40.

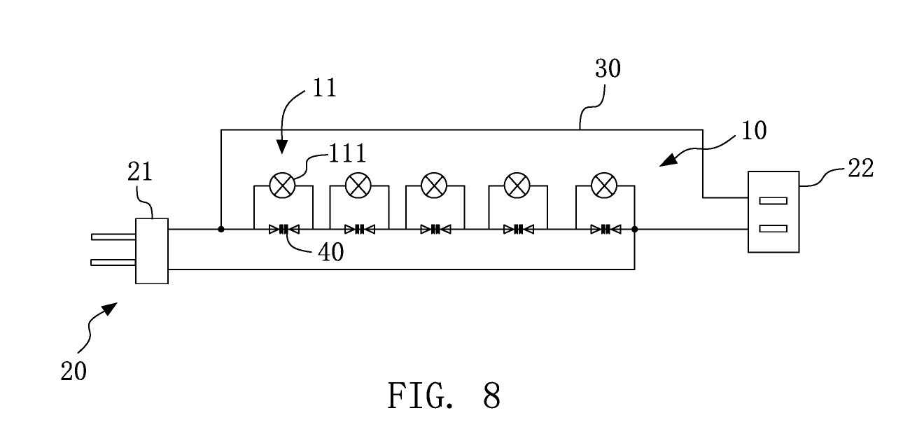

As shown in FIG. 1 to FIG. 4, and FIG. 8 to FIG. 10, the Christmas decorative lamp structure with safety arrangement according to the preferred embodiment of the present invention comprises a number of sets of light emitting elements 10. The number of sets of light emitting elements 10 can be one set or more than one set, depending on the height of a Christmas tree of a surface area and size of the Christmas tree. Each set of light emitting elements 10 comprises a plurality of light emitting elements 11, wherein the light emitting element 11 can be LED lamp bead or tungsten lamp bead. According to this preferred embodiment, the light emitting element 11 is a tungsten lamp bead with a rated voltage of 3.5V and a current of 0.12 A. FIG. 8 is an illustration of a circuit diagram of one set of light emitting elements. As shown in the FIG. 8, a plurality of light emitting elements 11 are spacedly connected in series on the connecting wire 30. The light emitting element 11 comprises a light bead 111 and a light holder 112. The light bead 111 has one end terminal connecting to the light holder 112. The light holder 112 is electrically connected to the connecting wire 30.

Referring to FIG. 1 to FIG. 4, the light bead 111 comprises a light emitting portion 1111 and a connecting portion 1112. The light emitting portion 1111 has a columnar structure. The light emitting portion 1111 can also has a ball-shaped structure or other structure and its structural construction of filament and connecting elements are the same as the conventional light bead. The connecting portion 1112 is made of insulating materials. The connecting portion 1112 has an inner side having rib-like projections 11121 for securing the light emitting portion 1111 into position. The connecting portion 1112 has an outer side having rib-like projections 11122 for engaging with the positioning projections 11212 to limit its rotation in the light holder along the circumferential direction.

The light emitting portion 1111 is inserted into the connecting portion 1112. The light emitting portion 1111 has two electrode wires 11111 extended and bended to an outer side from a tail portion of the connecting portion 1112, and are electrically connected to a conductive sheet 1122 inside the light holder 112 and an electrode 41 of the bidirectional diode 40.

Referring to FIG. 1 to FIG. 4 of the drawings, the light holder 112 comprises a main body 1121, a conductive sheet 1122 and a diode support 1123, wherein the main body 1121 of the light holder is made of insulating materials and has a sleeve-shaped body. The main body 1121 of the light holder has a step element 11211 at an inner and upper side thereof for restricting the positioning of the light bead in such a manner that a bottom end of the rib-like projections 11122 at the outer side of the connecting portion of the light bead is limited to position at the step element 11211.

The main body 1121 of the light holder has an inner wall having two elongated and convex positioning projections 11212 which is arranged for embedding between two rib-like projections 11122 at the outer side of the connecting portion of the light bead so as to limit the rotation of the light bead 111 in the light holder along its circumferential direction.

The main body 1121 of the light holder has a cross-shaped groove 11212 on its inner wall at a bottom side, which is arranged for positioning the diode support 1123. The cross-shaped groove defines two sets of symmetrical groove portions and one conductive sheet 1122 is secured on each of the symmetrical groove portion in one set of symmetrical groove portions and the conductive sheet 1122 is electrically connected to the connecting wire 30.

The diode support 1123 has a diode connecting portion 11231 and an extending portion 11232. The diode connection portion 11231 has a cross-shaped block structure and has a diode positioning hole 112311 transversely provided thereon. The diode connection portion 11231 has a bottom portion which is downwardly extended to form the extending portion 11232. The diode support 1123 is inserted inside the cross-shaped groove 11212 at the bottom side of the main body of the light holder.

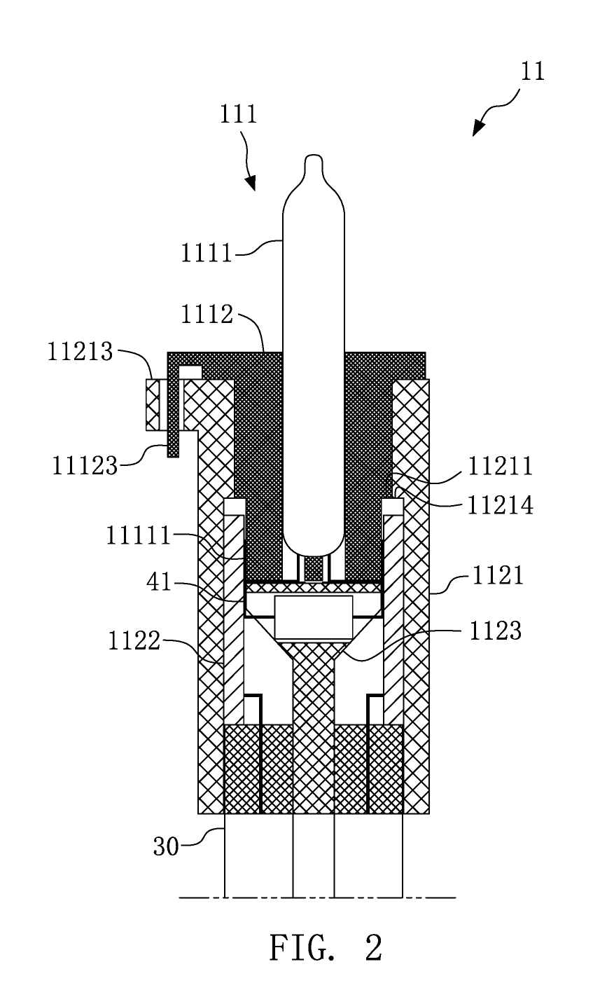

Referring to FIG. 2 of the drawings, the light bead 111 and the light holder 112 are connected by plug-in connection. In particular, the light bead 111 is inserted into the main body 1121 of the light holder, and the two electrode wires 11111 of the light bead are electrically connected to the conductive sheet 1122 of the light holder and the electrode 41 of the bidirectional diode 40.

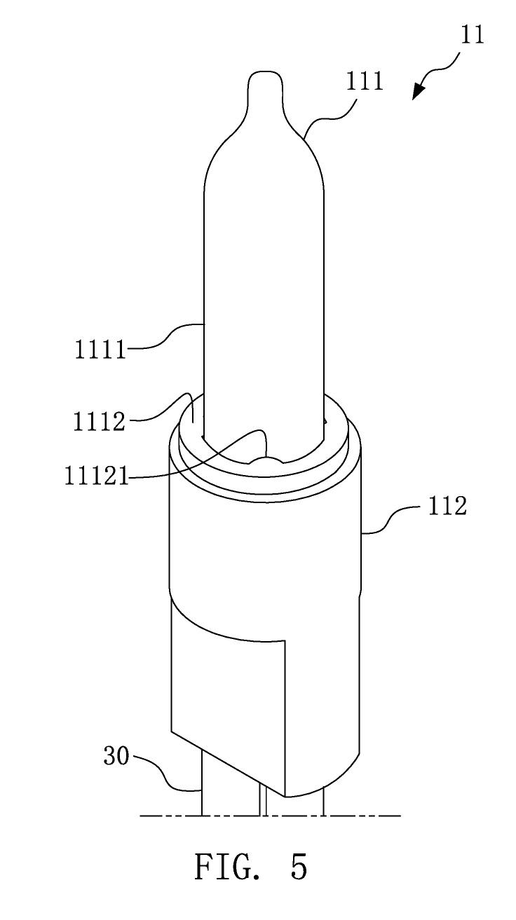

In order to prevent the light bead 111 from moving within the main body of the light holder due to looseness, according to a preferred embodiment of the present invention, the main body 1121 of the light holder has a U-shaped snap seat 11213 protruded outwardly at an outer side on an upper portion thereof. The sleeve body of the connecting portion 1112 of the light bead has a corresponding bendable buckle 11123 at its outer side. As shown in FIG. 1 and FIG. 2, after the light bead 111 is inserted into the main body 1121 of the light holder, the buckle 11123 of the light bead is bended and snapped into the snap seat 11213 of the main body of the light holder so that the light bead 111 is prevented from upward or downward movement or rotation in the main body 1121. As shown in FIG. 5 to FIG. 7, according to another preferred embodiment of the present invention, the light bead 111 is inserted directly inside the main body 1121 of the light holder and are secured into position through engaging the rib-like projections 11122 at the outer side of the connecting portion of the light bead with the positioning projections 11212 at the inner wall of the main body of the light holder.

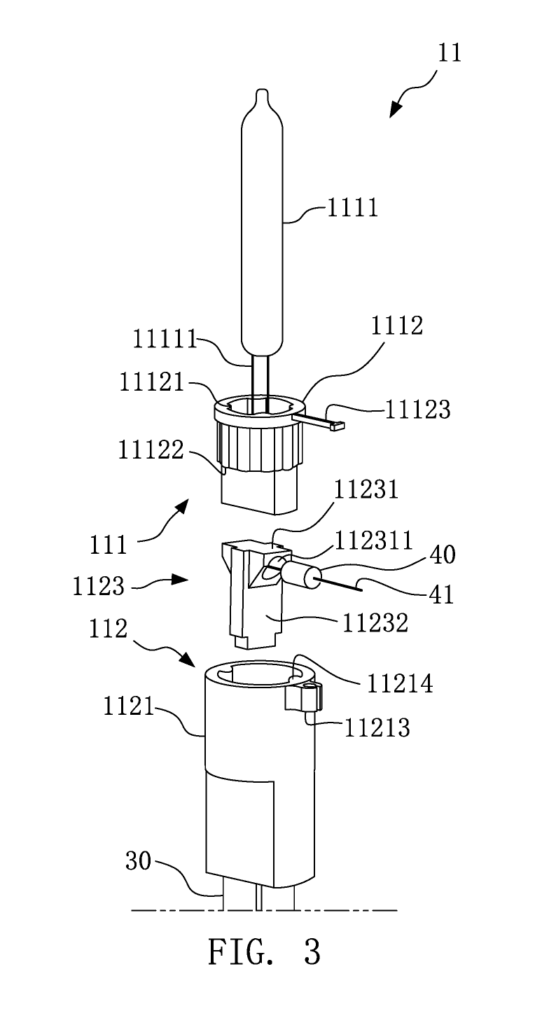

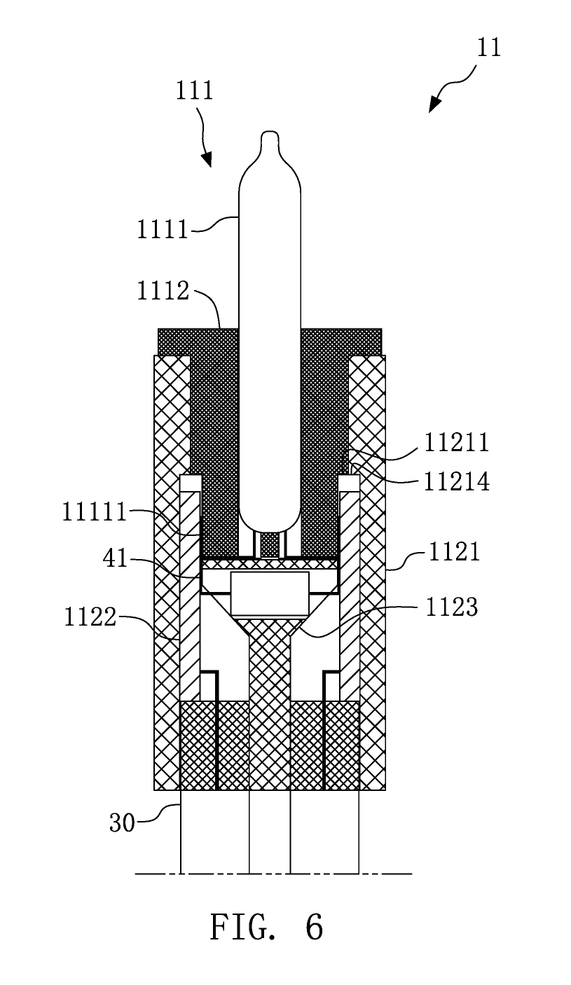

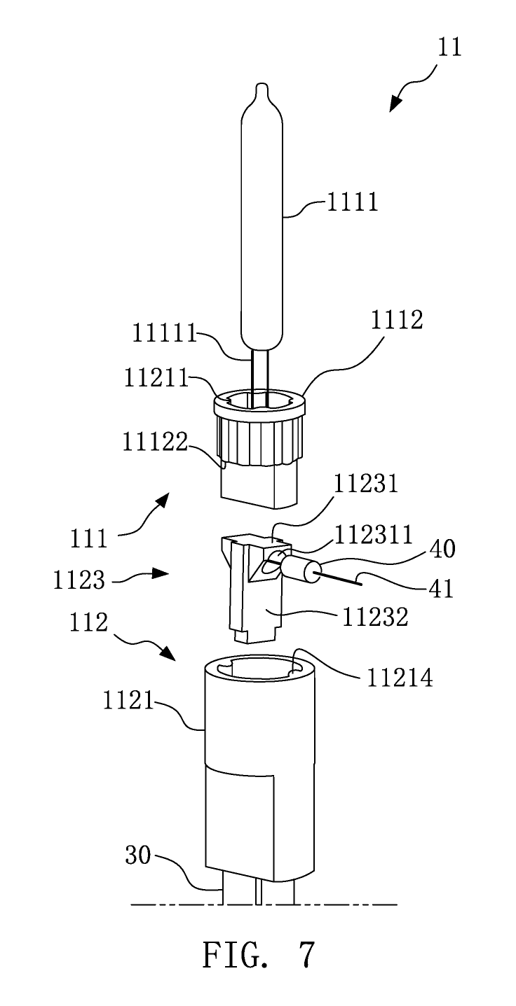

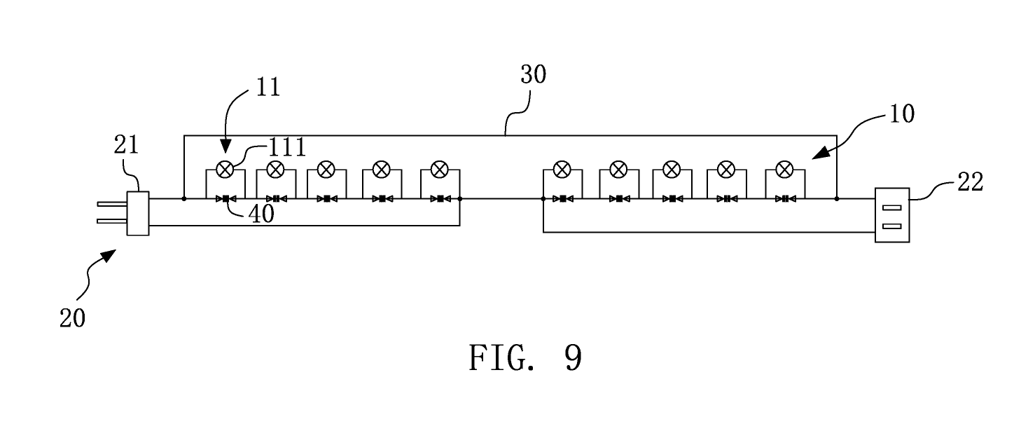

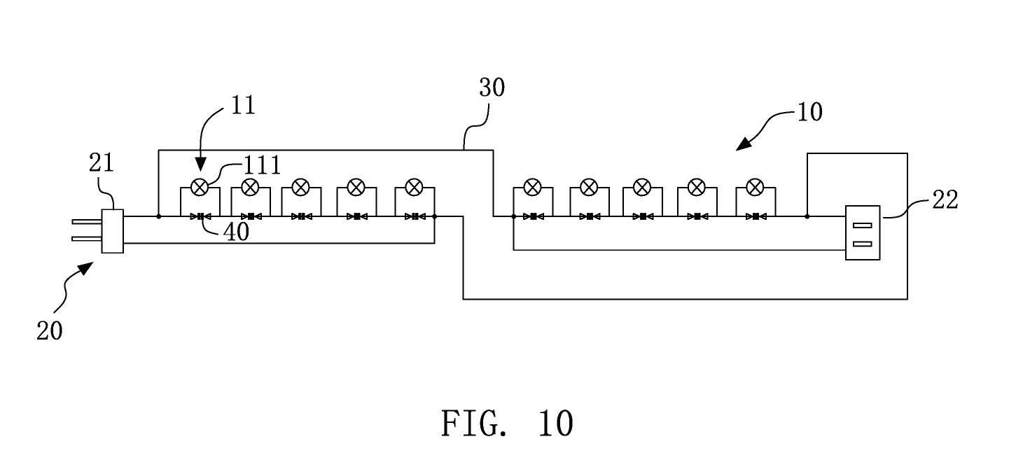

Referring FIG. 2, FIG. 3, FIG. 6, FIG. 7, FIG. 8, FIG. 9 and FIG. 10 of the drawings, according to the preferred embodiment of the present invention, each of the light emitting elements is connected to a bidirectional diode in parallel such that when one or more of the light emitting elements 11 in the same set of light emitting elements 10 is faulty or damaged, the rest of the light emitting elements in the same set is protected against damage from excessive high voltage. In particular, the bidirectional diode 40 is secured inside the diode positioning hole 112311 of the diode support, the two electrodes 41 of the bidirectional diode 40 is extended from two sides of the diode connecting portion 11231 and bended to a top portion thereof in such a manner that the two electrodes 41 are connect to the two electrode wires 11111 of the light bead, thereby when thereby when one or more of the light emitting element is faulty or damaged, the bidirectional diode 40 of the faulty or damaged light emitting element 11 is triggered and turned on so that the voltage of light emitting elements of the same set of light emitting elements which is not faulty or damaged is remained unchanged, therefore the set of light emitting elements are capable of working safely under a constant voltage.

Referring to FIG. 8 to FIG. 10 of the drawings, the connecting wire 30 has two terminals connecting to the power connector 20 respectively. The power connector 20 comprises a power plug 21 and a power socket 22. The power plug 21 is provided at one end of the connecting wire arranged for connecting to a power socket of an external power source. The power socket 22 is arranged at the other end of the connecting wire 30. When it is needed to connect to another set of light emitting elements 10, the power plug of the other set of light emitting elements 10 is plugged into the power socket 22. Through this structural construction, a plurality set of light emitting elements can be connected together. Accordingly, the set of light emitting elements can be expanded easily to fit the actual need of decorative requirements.

Referring to FIG. 8 of the drawings, which shows the schematic circuit diagram of one set of light emitting elements. According to this embodiment, the plurality of light emitting elements 11 are connected in series. Each of the light emitting elements has a rated voltage of 3.5V and a current of 0.12 A. The number of light emitting elements 11 are 35, and the voltage of the whole set of light emitting elements is 120V. For each light emitting element 11, a bidirectional diode 40 is connected in parallel. When a particular light emitting element 11 is faulty or damaged, the corresponding bidirectional diode 40 of the faulty or damaged light emitting element is turned on instantaneously. Therefore, the voltage on other normal light emitting elements is remained unchanged and the set of light emitting elements can still work properly.

Referring to FIG. 9 and FIG. 10 of the drawings, which shows the other preferred embodiments, there are two set of light emitting elements 10. The two sets of light emitting elements 10 are connected in parallel. The connecting wires on two ends of the two sets of light emitting elements 10 are connected with the power connector 20.

According to the present invention, a bidirectional diode is connected in parallel to each of the light emitting elements of the set of light emitting elements in Christmas decorative lighting so that when one or more light emitting elements are broken or damaged, the normal light emitting elements in the same set can still work under normal voltage, therefore the Christmas decorative light can still work properly and safely.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A decorative lamp structure with safety arrangement, comprising:
at least one set of light emitting elements, a power connector and a connecting wire, characterized in that:
each said set of light emitting elements comprises:
a plurality of light emitting elements connected in series to the said connecting wire,
wherein each said light emitting element connected to a bidirectional diode in parallel,
thereby when one or more of said light emitting element is faulty or damaged, said bidirectional diode of said faulty or damaged light emitting element is triggered and turned on so that said light emitting elements of said set of light emitting elements which is not faulty or damaged are capable of working safely at a constant voltage,
wherein said connecting wire has two terminals connecting to said power connector respectively.

2. The decorative lamp structure with safety arrangement according to claim 1, wherein each said light emitting element comprises a light bead and a light holder, wherein said light bead has one end plugging to connect to said light holder, wherein said light holder electrically connected to said connecting wire.

3. The decorative lamp structure with safety arrangement according to claim 2, wherein said light bead comprises a light emitting portion having a columnar structure and a connecting portion plugging to connect to said light emitting portion, wherein said connecting portion is made of insulating materials and has rib-like projections on its inner side and its outer side respectively, wherein said light emitting portion is inserted into said connecting portion, wherein said light emitting portion has two electrode wires extended outside from a tail portion of said connecting portion and folded to an outer side.

4. The decorative lamp structure with safety arrangement according to claim 3, wherein said light emitting element is LED lamp bead or tungsten lamp bead.

5. The decorative lamp structure with safety arrangement according to claim 2, wherein said light holder comprises a main body, a conductive sheet and a diode support, wherein said main body of said light holder is made of insulating materials and has a sleeve-shaped construction, wherein said main body of said light holder has a step element at an inner and upper side thereof, said main body of said light holder has a cross-shaped groove on an inner wall at a bottom side thereof, wherein said cross-shaped groove has two sets of symmetrical groove portions and one conductive sheet is secured on each said symmetrical groove portion of one said set of symmetrical groove portions, wherein said conductive sheet is electrically connected to said connecting wire, wherein said diode support has a cross-shaped diode connecting portion and an extending portion downwardly extended from said diode connecting portion, wherein said diode connecting portion has a diode positioning hole transversely provided thereon, wherein said diode support is inserted inside said cross-shaped groove of said main body of said light holder.

6. The decorative lamp structure with safety arrangement according to claim 3, wherein said light holder comprises a main body, a conductive sheet and a diode support, wherein said main body of said light holder is made of insulating materials and has a sleeve-shaped construction, wherein said main body of said light holder has a step element at an inner and upper side thereof, said main body of said light holder has a cross-shaped groove on an inner wall at a bottom side thereof, wherein said cross-shaped groove has two sets of symmetrical groove portions and one conductive sheet is secured on each said symmetrical groove portion of one said set of symmetrical groove portions, wherein said conductive sheet is electrically connected to said connecting wire, wherein said diode support has a cross-shaped diode connecting portion and an extending portion downwardly extended from said diode connecting portion, wherein said diode connecting portion has a diode positioning hole transversely provided thereon, wherein said diode support is inserted inside said cross-shaped groove of said main body of said light holder.

7. The decorative lamp structure with safety arrangement according to claim 5, wherein said main body of said light holder has a U-shaped snap seat protruded outwardly at an outer side on an upper portion, wherein said connecting portion of said light bead has a bendable buckle at an outer side for coupling with said snap seat.

8. The decorative lamp structure with safety arrangement according to claim 6, wherein said main body of said light holder has a U-shaped snap seat protruded outwardly at an outer side on an upper portion, wherein said connecting portion of said light bead has a bendable buckle at an outer side for coupling with said snap seat.

9. The decorative lamp structure with safety arrangement according to claim 5, wherein said bidirectional diode is secured inside said diode positioning hole of said diode support, wherein said bidirectional diode has two electrodes extended from two sides of said diode connecting portion and bended to a top portion thereof so as to connect to said two electrode wires of said light bead.

10. The decorative lamp structure with safety arrangement according to claim 6, wherein said bidirectional diode is secured inside said diode positioning hole of said diode support, wherein said bidirectional diode has two electrodes extended from two sides of said diode connecting portion and bended to a top portion thereof so as to connect to said two electrode wires of said light bead.

11. The decorative lamp structure with safety arrangement according to claim 1, wherein said power connector comprises a power plug at one end of said connecting wire and a power socket at the other end of said connecting wire, wherein said power plug is arranged for connecting to an external power source while said power socket is arranged for expansion for connecting to other power plug of another set of light emitting elements.

12. The decorative lamp structure with safety arrangement according to claim 3, wherein said power connector comprises a power plug at one end of said connecting wire and a power socket at the other end of said connecting wire, wherein said power plug is arranged for connecting to an external power source while said power socket is arranged for expansion for connecting to other power plug of another set of light emitting elements.

13. The decorative lamp structure with safety arrangement according to claim 5, wherein said power connector comprises a power plug at one end of said connecting wire and a power socket at the other end of said connecting wire, wherein said power plug is arranged for connecting to an external power source while said power socket is arranged for expansion for connecting to other power plug of another set of light emitting elements.

14. The decorative lamp structure with safety arrangement according to claim 8, wherein said power connector comprises a power plug at one end of said connecting wire and a power socket at the other end of said connecting wire, wherein said power plug is arranged for connecting to an external power source while said power socket is arranged for expansion for connecting to other power plug of another set of light emitting elements.

15. The decorative lamp structure with safety arrangement according to claim 10, wherein said power connector comprises a power plug at one end of said connecting wire and a power socket at the other end of said connecting wire, wherein said power plug is arranged for connecting to an external power source while said power socket is arranged for expansion for connecting to other power plug of another set of light emitting elements.

16. The decorative lamp structure with safety arrangement according to claim 1, wherein said decorative lamp structure with safety arrangement comprises more than one set of light emitting elements and said sets of light emitting elements are connected in parallel.

17. The decorative lamp structure with safety arrangement according to claim 3, wherein said decorative lamp structure with safety arrangement comprises more than one set of light emitting elements and said sets of light emitting elements are connected in parallel.

18. The decorative lamp structure with safety arrangement according to claim 5, wherein said decorative lamp structure with safety arrangement comprises more than one set of light emitting elements and said sets of light emitting elements are connected in parallel.

19. The decorative lamp structure with safety arrangement according to claim 8, wherein said decorative lamp structure with safety arrangement comprises more than one set of light emitting elements and said sets of light emitting elements are connected in parallel.

20. The decorative lamp structure with safety arrangement according to claim 15, wherein said decorative lamp structure with safety arrangement comprises more than one set of light emitting elements and said sets of light emitting elements are connected in parallel.
